(19) United States
(12) Patent Application Publication
(10) Pub. No.: US 2014/0153200 A1
(43) Pub. Date: Jun. 5, 2014

(54) PRINTED CIRCUIT BOARD

(71) Applicant: HON HAI PRECISION INDUSTRY CO., LTD., New Taipei (TW)

(72) Inventor: SHAO-YOU TANG, New Taipei (TW)

(73) Assignee: HON HAI PRECISION INDUSTRY CO., LTD., New Taipei (TW)

(21) Appl. No.: 14/086,982

(22) Filed: Nov. 22, 2013

(30) Foreign Application Priority Data
Dec. 4, 2012 (TW) 101145365

(51) Int. Cl. H05K 1/02

(52) U.S. Cl. CPC H05K 1/0236
USPC 361/748; 174/262; 174/260

(57) ABSTRACT

A printed circuit board includes a ground layer, a metal board, a via, and a power layer. The metal board is arranged between the ground layer and the power layer. The via is electrically connected between the metal board and the power layer. The power layer is made of a number of wires.

### BACKGROUND

1. Technical Field

The present disclosure relates to a printed circuit board.

2. Description of Related Art

An electromagnetic band-gap (EBG) structure is used to reduce simultaneous switching noise (SSN) in design of printed circuit boards. The EBG structure includes a metal board 1 and a via 2 as shown in FIG. 1. The metal board 1 and the via 2 form a capacitor and an inductor connected in series as shown in FIG. 2. The series circuit is short under a resonant frequency to transmit the SSN from a power layer 5 to a ground layer 3 to reduce the SSN. However, effect of the series circuit in reducing the SSN is not significant.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a schematic view of a printed circuit board (PCB) in the prior art.

FIG. 2 is an equivalent circuit diagram of an electromagnetic band-gap (EBG) structure of the PCB of FIG. 1.

FIG. 3 is a schematic view of an embodiment of a PCB of the present disclosure.

FIG. 4 is an equivalent circuit diagram of an EBG structure of the PCB of FIG. 3.

FIG. 5 is a curve diagram showing the complex frequency domain of the PCB in the prior art of FIG. 1 and the PCB of FIG. 3.

FIG. 6 is a dispersion diagram of the PCB of FIG. 1.

### DETAILED DESCRIPTION

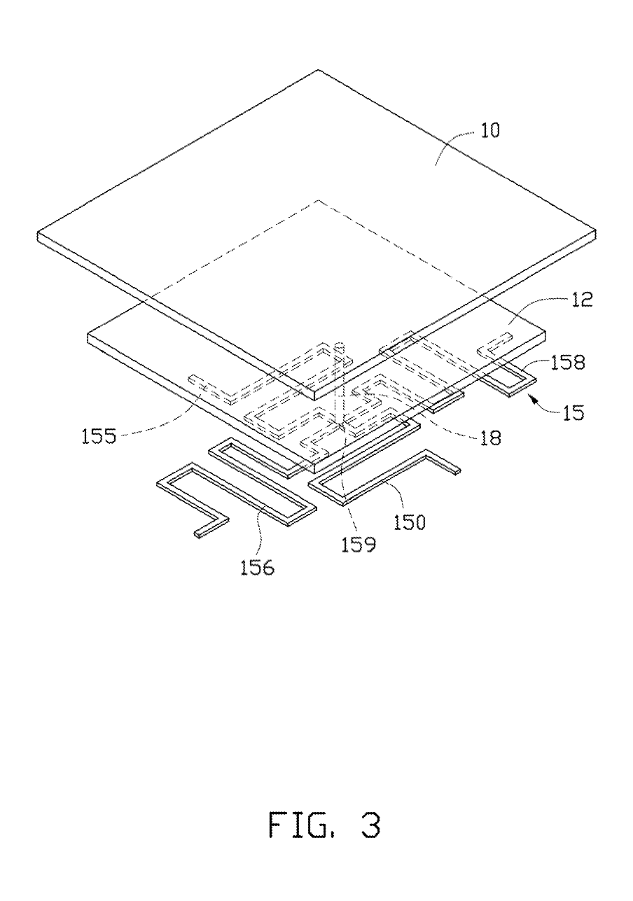

FIG. 3 shows an embodiment of a printed circuit board (PCB) of the present disclosure.

The PCB includes a ground layer 10, a metal board 12, a power layer 15, and a via 18. The metal board 12 is arranged between the ground layer 10 and the power layer 15.

In this embodiment, the power layer 15 is made of wires. The via 18 is electrically connected between the power layer 15 and the metal board 12. The wires are bent to generate inductance. Each wire together with a neighboring wire generate capacitance. Therefore, simultaneous switching noise (SSN) is reduced due to the inductance and the capacitance.

In one embodiment, the power layer 15 includes a first wire 150, a second wire 155, a third wire 156, and a fourth wire 158. An end of each of the wires 150, 155, 156, and 158 is connected to a central terminal 159. The first wire 150 and the second wire 155 are opposite each other about the central terminal 159. The third wire 156 and the fourth wire 158 are opposite each other about the central terminal 159.

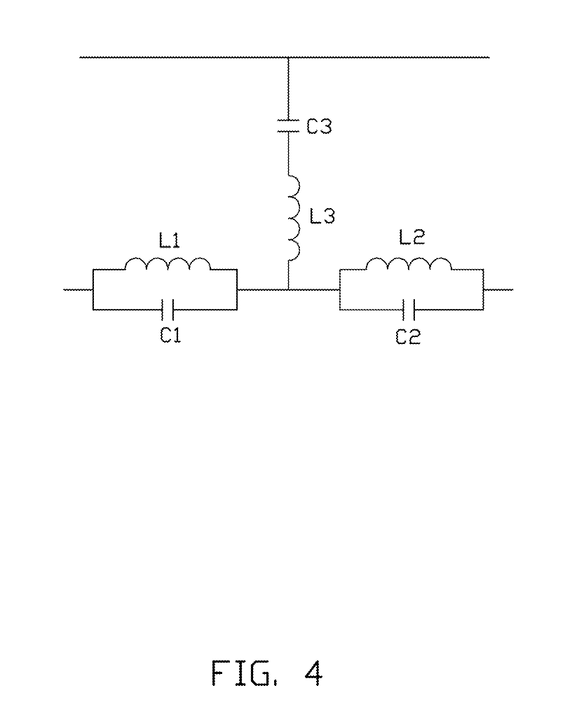

FIG. 4 is an equivalent circuit diagram of the PCB of the present disclosure. A first parallel circuit made up of a capacitor C1 and an inductor L1 and a second parallel circuit made up of a capacitor C2 and an inductor L2 are generated by the first to fourth wires. The first parallel circuit and the second parallel circuit will be open under a resonant frequency that reduces the SSN on the power layer 15 significantly. A series circuit made up of a capacitor C3 and an inductor L3 is an equivalent circuit which is generated by the PCB.

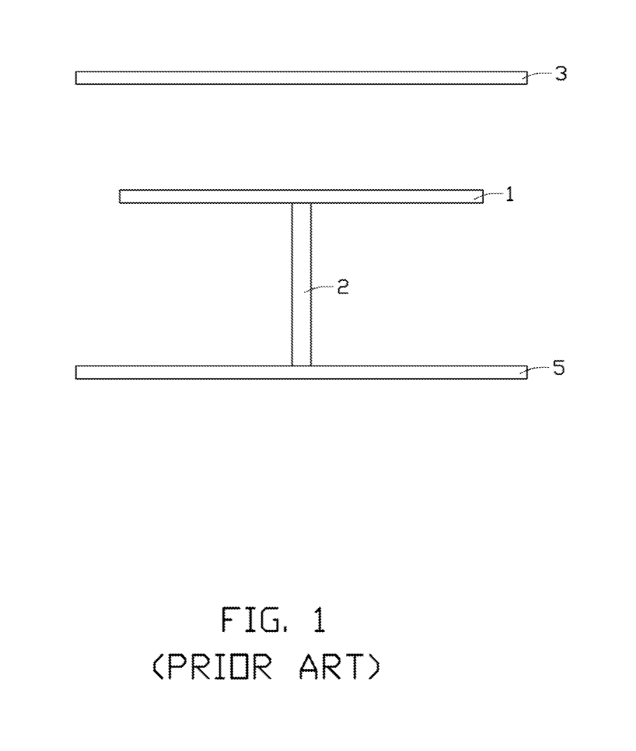

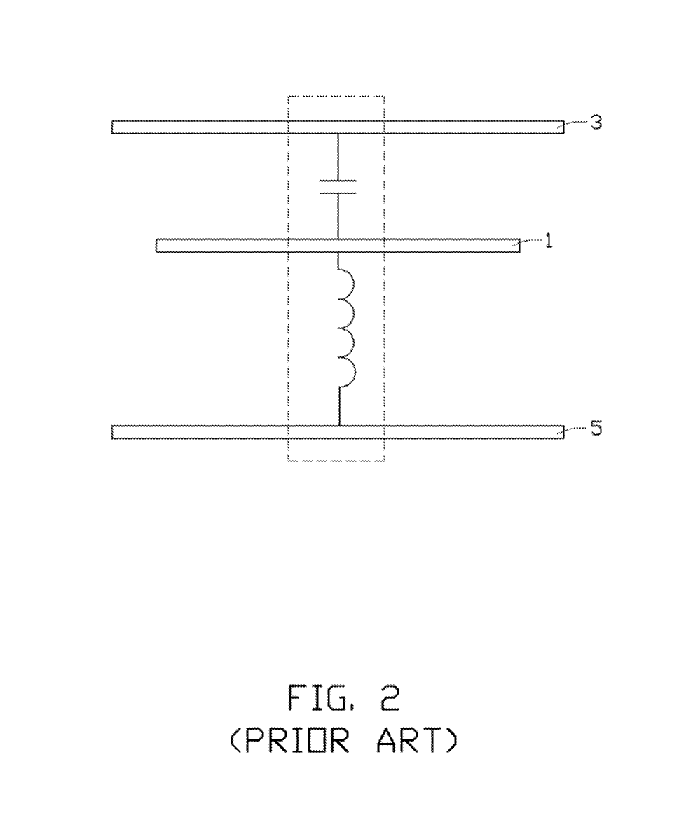

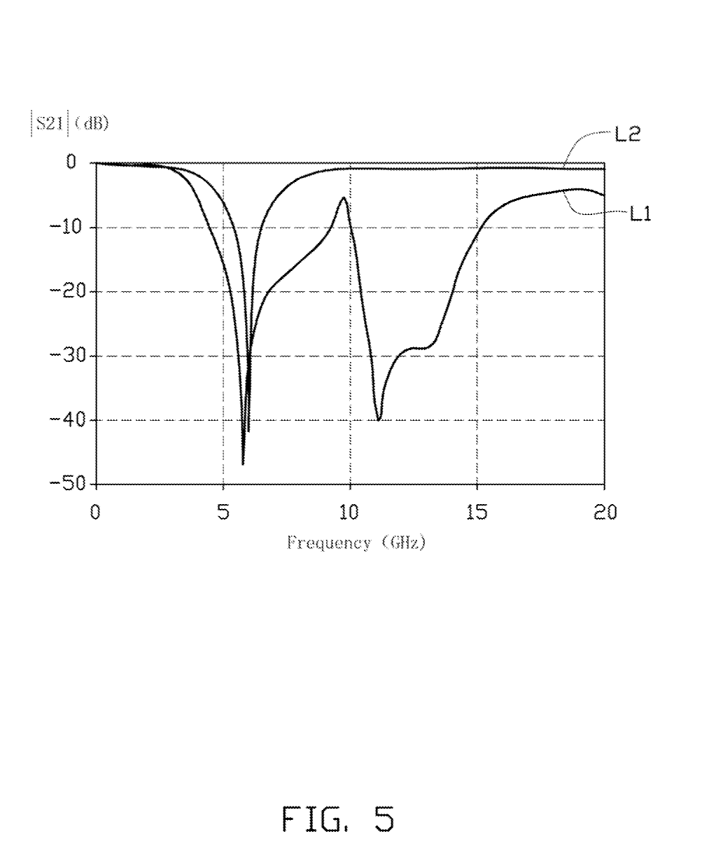

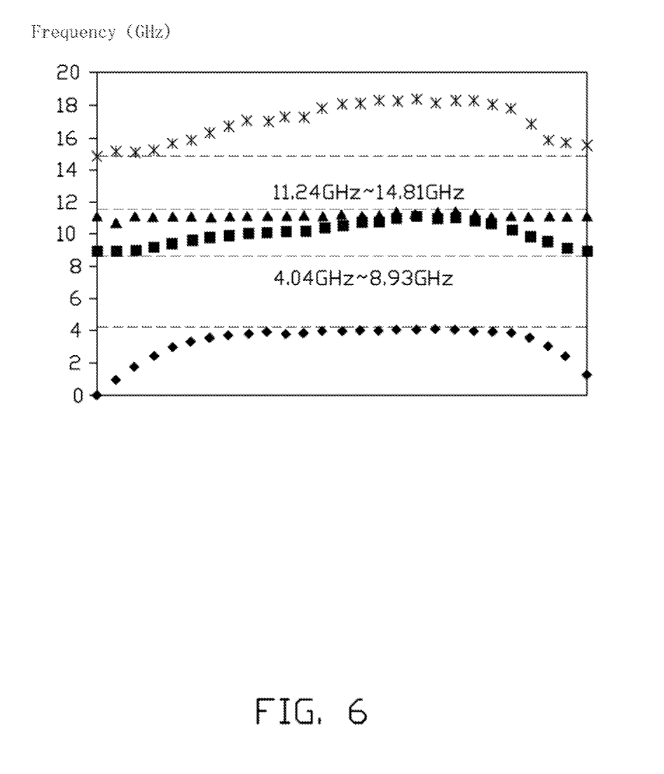

FIG. 5 and FIG. 6 show simulation results of the PCB in the embodiment and the PCB in the prior art of FIG. 1 and FIG. 2. FIG. 5 is a simulation result in the complex frequency domain with L2 representing the PCB of the prior art of FIG. 1 and FIGS. 2, and L1 representing the PCB of the embodiment. L1 has a greater forbidden zone which can effectively restrain noise. FIG. 6 is a dispersion diagram of the PCB of the embodiment. The two forbidden zones in FIG. 6 show that the PCB of the embodiment has two bands 4.04 GHz-8.93 HGz, and 11.24 GHz-14.81 GHz, in which the SSN cannot exist.

While the disclosure has been described by way of example and in terms of preferred embodiment, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A printed circuit board (PCB) comprising a ground layer, a metal board, a via, and a power layer, wherein the metal board is arranged between the ground layer and the power layer, the via is connected between the metal board and the power layer, and the power layer comprises a plurality of wires.

2. The PCB of claim 1, wherein the plurality of wires intersect at a central terminal, a first end of the via is electrically connected to the central terminal, and a second end of the via is connected to the metal board, the plurality of wires are bent to generate inductance, each wire together with a neighboring wire generate capacitance.

3. The PCB of claim 2, wherein the plurality of wires comprises a first wire and a second wire, the first wire and the second wire are opposite each other about the central terminal, and an end of each of the first and second wires is connected to the central terminal

4. The PCB of claim 3, wherein a first parallel circuit made up of a first capacitor and a first inductor is generated by the first wire and second wire.

5. The PCB of claim 4, wherein the plurality of wires further comprises a third wire and a fourth wire, the third wire and the fourth wire are opposite each other about the central terminal, and an end of each of the third and fourth wires is connected to the central terminal.

6. The PCB of claim 5, wherein a second parallel circuit made up of a second capacitor and an second inductor are generated by the third wire and the fourth wire, the first parallel circuit is connected to the second parallel circuit, a node between the first parallel circuit and the second parallel circuit is connected to a third capacitor through a third resistor, wherein the third capacitor and the third resistor are generated by the PCB.

7. The PCB of claim 6, wherein the PCB has two bands 4.04 GHz-8.93 HGz, and 11.24 GHz-14.81 GHz, in which simultaneous switching noise cannot exist.
